(19) United States
(12) Patent Application Publication
(10) Pub. No.: US 2026/0305174 A1
(43) Pub. Date: Oct. 1, 2026

(54) METHOD FOR PREPARING A SINGLE-DOMAIN THIN LAYER MADE OF LITHIUM-CONTAINING FERROELECTRIC MATERIAL

(71) Applicant: Soitec, BERNIN (FR)

(72) Inventors: Alexis Drouin, BERNIN (FR); Rénald Guerin, BERNIN (FR); Marcel Broekaart, BERNIN (FR); Luciana Capello, BERNIN (FR); Sabrina Lakhal, BERNIN (FR)

(21) Appl. No.: 18/992,008

(22) PCT Filed: Jun. 29, 2023
(86) PCT No.: PCT/EP2023/067802

§ 371 Date: Jan. 7, 2025

(30) Foreign Application Priority Data
Jul. 29, 2022 (FR) FR2207841

(51) Int. Cl. H10N 30/072; H10N 30/086; H10P 70/00

(52) U.S. Cl. CPC H10N 30/072; H10N 30/086; H10P 70/20

(57) ABSTRACT

A method for preparing a single-domain thin layer made of lithium-containing ferroelectric material includes providing a first single-domain layer of lithium-containing ferroelectric material, the layer being bonded to a carrier, the first single-domain layer having a lithium-rich surface thickness. The method further includes a first step of wet cleaning of the free side of the first single-domain layer, the wet cleaning step being able to remove the lithium-rich surface layer. The method includes a second step that aims to remove or prevent the appearance of lithium-rich and hydrogen-rich dendrites liable to nucleate on the free side of the first single-domain layer when it is devoid of the lithium-rich surface layer.

### CROSS-REFERENCE TO RELATED APPLICATIONS

This application is a national phase entry under 35 U.S.C. § 371 of International Patent Application PCT/EP2023/067802, filed Jun. 29, 2023, designating the United States of America and published as International Patent Publication WO 2024/022723 A1 on Feb. 1, 2024, which claims the benefit under Article 8 of the Patent Cooperation Treaty of French Patent Application Serial No. FR2207841, filed Jul. 29, 2022.

### TECHNICAL FIELD

The present disclosure relates to a structure of the piezoelectric-on-insulator (POI) type. Such a structure is particularly useful in the fields of microelectronics, microsystems, photonics, etc. In particular, it can be used to form or build radio frequency (RF) components, particularly filters or resonators based on elastic wave components, such as surface elastic waves.

### BACKGROUND

With reference to FIGS. 1A and 1B, which show state-of-the-art POI structures, a POI structure is typically formed by a piezoelectric thin layer 4 applied to a first face of a carrier 2. A dielectric interlayer 3 is arranged between, and in contact with, the carrier 2 and the thin layer 4.

The thin layer 4 consists of a single-crystal piezoelectric material, such as lithium tantalate or lithium niobate. These materials also exhibit ferroelectric properties. Recall that a ferroelectric material is one that possesses spontaneous electrical polarization in its natural state. The thin layer 4 of a POI structure must be uniformly polarized, i.e., all dipole moments must be aligned parallel to each other in a given direction.

The carrier 2 is preferably selected to be made of silicon. The substrate may be a single-crystal silicon base substrate with a resistivity in excess of 1000 Ohms·cm. Alternatively, and as shown in FIG. 1B, the carrier 2 may be formed by a base substrate 2a on which an electric charge trapping layer 2b is arranged. In this alternative, the dielectric interlayer 3 is arranged in contact with the trapping layer 2b.

The document WO2020200986A1 proposes a method for manufacturing such a POI substrate that preserves the single-domain character of the thin layer. This document provides for transferring a layer taken from a donor substrate comprising a piezoelectric material onto the carrier 2, via a step of implanting a light species in accordance with the principles of Smart Cut™ technology. Following this transfer, the removed layer is processed in a finishing sequence comprising a heat treatment followed by a polishing step, this finishing sequence leading to the formation of the single-domain, single-crystal, piezoelectric thin layer 4. During this sequence, it was observed that the heat treatment led to the formation of a multi-domain surface portion on the sampled layer, this multi-domain surface portion then being removed by the subsequent polishing treatment, resulting in the thin layer 4 having the required single-domain quality.

However, under certain conditions, in particular, when light species are implanted in high doses and/or at high currents to increase production rates, defects have been observed in the thin layer 4. A first type of defect observed, with reference to FIG. 2, consists in the presence of a depression D1, or sometimes even a protuberance, on the surface of the thin layer, these depressions/protuberances D1 making the thickness of the thin layer 4 non-uniform. These defects D1, referred to as “depression-type defects” for simplicity's sake, visible on the left-hand insert of FIG. 2, are generally circular or elliptical in shape, with dimensions (diameter or major axis) on the order of 1 micron to 100 microns, and which can sometimes have a high aspect ratio. They typically have a depth or elevation of between 1 and 30 nanometers relative to the exposed surface of the thin layer 4.

A second type of defect observed is the presence of “triangle defects” D2. These defects take the form of ferroelectric domain inversion bars with triangular cross-sections ranging from 0.1 microns to 10 microns on a side, as can be seen in the insert on the right of FIG. 2. The bars emerge from the surface of the thin layer 4 and extend into the thickness of the thin layer 4 and, in some cases, through it. They are oriented in a direction antiparallel to the spontaneous polarization direction Ps of the piezoelectric thin layer 4. These triangular defects may have a density greater than 10³/cm² on the exposed surface of the thin layer 4.

Both types of defect, depressions and triangle defects, have a significant impact on the performance of devices, such as acoustic filters, formed on and in POI substrates.

### BRIEF SUMMARY

It is an object of the present disclosure to address this problem at least in part. More specifically, one aim of the present disclosure is to provide a piezoelectric-on-insulator structure whose piezoelectric thin layer is free of depression-type defects or triangular defects or, at the very least, has defects in a lower density than a piezoelectric thin layer obtained by a method of the prior art.

In order to achieve this aim, the present disclosure proposes a method for preparing a single-domain thin layer of lithium-containing ferroelectric material, the method comprising:
providing a first single-domain layer of lithium-containing ferroelectric material, the layer being bonded to a carrier, the first layer having a lithium-rich surface thickness;
finishing the first layer, this finishing comprising heat treatment of the free side of the first layer, followed by a step of thinning the first layer to form the single-domain thin layer.

The preparation method is remarkable in that it comprises, prior to the heat treatment:
a first step of wet cleaning of the free side of the first layer, the cleaning step being able to remove the lithium-rich surface layer;
a second step of preparing the first layer to eliminate, prevent, or limit the appearance of lithium-rich and hydrogen-rich dendrites liable to nucleate on the free side of the first layer when it is devoid of the lithium-rich surface layer.

According to other advantageous non-limiting features of the present disclosure, taken alone or according to any technically feasible combination:
the providing of the first layer comprises:
   implanting light species in a first face of a lithium-containing ferroelectric donor substrate to form an embrittlement plane and define the first layer between the embrittlement plane and the first face of the donor substrate;
assembling the first face of the donor substrate to the carrier by way of a dielectric interlayer;
fracturing the donor substrate at the embrittlement plane to transfer the first layer onto the support substrate and expose a free side of the first layer to the atmosphere, this exposure leading to the formation of the lithium-rich surface thickness.
the first cleaning step comprises brushing and dispensing deionized water onto the free side of the first layer;
the second preparation step is a wet cleaning step of the free side of the first layer;
the second preparation step comprises brushing and dispensing deionized water onto the free side of the first layer;
the second preparation step is designed to remove dendrites and is applied at least 50 hours, preferably at least 75 hours, after the application of the first cleaning step;
the preparation method comprises an intermediate step, between the first preparation step and the second preparation step, the intermediate step exposing the first layer to a temperature above ambient temperature;
the second preparation step is designed to prevent or limit the appearance of dendrites and is applied less than 50 hours, preferably less than 10 hours, after the application of the first cleaning step;
the second preparation step comprises exposing the free side of the first layer to a plasma;
the plasma is selected from the list consisting of an O₂ plasma, an N₂ plasma and a fluorine-based plasma, such as an SF₆ or CₓH_{y}F_{z} plasma, or a combination of these plasmas;
the support is formed by a single-piece electrically conductive or semiconductive substrate;
the support comprises a base substrate and a trapping layer, the trapping layer being arranged between the dielectric interlayer and the base substrate;
the first layer and the thin layer are made of a single-crystal piezoelectric material, such as lithium tantalate or lithium niobate;
the first layer and the thin layer are made of lithium niobate;
the dielectric interlayer comprises at least one layer of silicon oxide, silicon oxynitride, or silicon nitride.

### BRIEF DESCRIPTION OF THE DRAWINGS

Other features and advantages of the present disclosure will emerge from the following detailed description of the present disclosure with reference to the appended figures, in which:

FIGS. 1A and 1B show state-of-the-art POI structures;

FIG. 2 shows the defects present in a thin layer of a POI structure;

FIG. 3 shows the steps of manufacturing a POI structure;

FIGS. 4A, 4B, 4C, and 4D show the state of the first layer and the thin layer of a POI structure during the various stages of its manufacture; and

FIG. 5 shows a method in accordance with the present disclosure.

### DETAILED DESCRIPTION

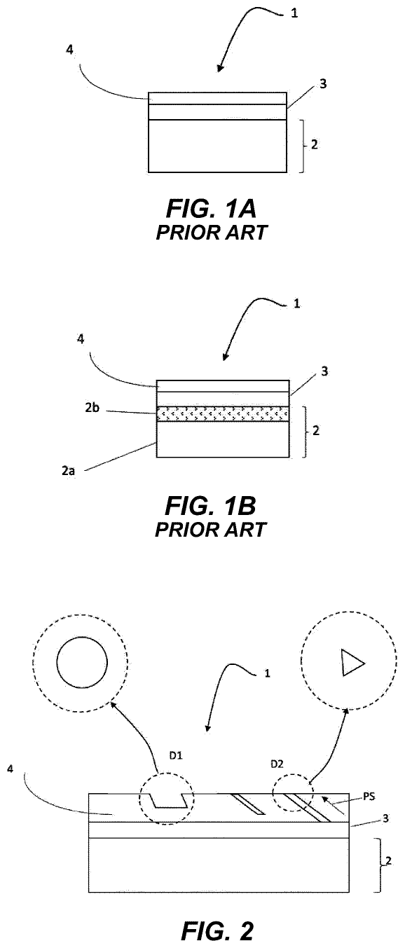

We begin by recalling the steps of a method for manufacturing a POI 1 structure as presented in the introductory part of the present disclosure and shown in FIGS. 1A and 1B.

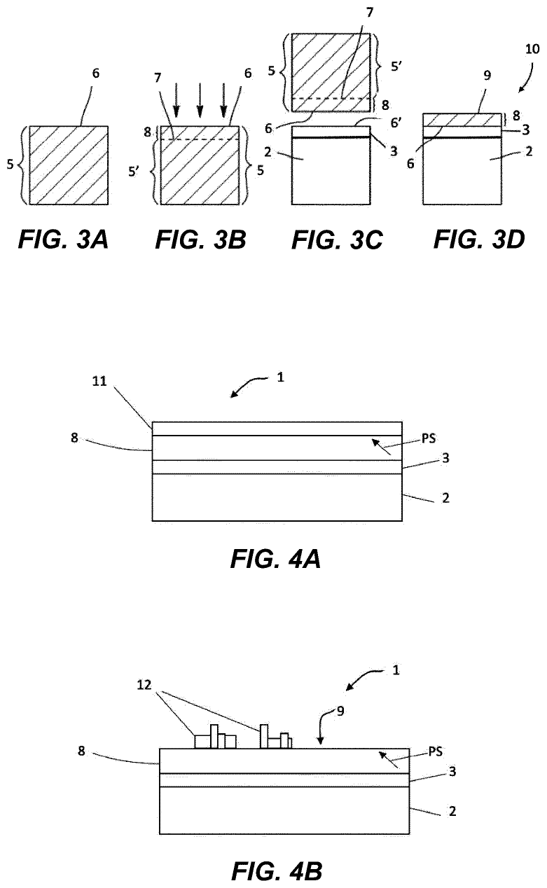

This method generally provides for transferring a first ferroelectric layer 8 onto a carrier 2, the first layer 8 being taken from a single-domain ferroelectric donor substrate 5 by a transfer technique based on the implantation of light species such as hydrogen and/or helium species. In the present disclosure, the ferroelectric material of the donor substrate 5 comprises lithium. It may, for instance, be lithium tantalate or lithium niobate. In addition to ferroelectric properties, the donor substrate material also has piezoelectric properties. The ferroelectric material advantageously has a crystal direction between 30° and 60° RY. The donor substrate 5 may be a homogeneous substrate consisting entirely of ferroelectric and piezoelectric material, as shown in FIG. 3, or it may be a composite substrate consisting of a homogeneous part, e.g., made of silicon, on which a thick layer of ferroelectric and piezoelectric material lies, from which the first layer is taken.

In some embodiments, the carrier 2 is a single-piece conductive or semiconductive substrate. In other embodiments, the carrier 2 comprises a base substrate 2a with a surface electric charge trapping layer 2b. This trapping layer 2b is arranged on the side of the first face of the carrier 2, which is intended to receive the thin layer 4. In these embodiments shown, the dielectric interlayer 3 is in contact with the trapping layer 2b and the thin layer 4.

According to the transfer technique based on the implantation of light species, and with reference to FIG. 3B, hydrogen and/or helium are implanted into a first face 6 of the donor substrate 5 to form a buried embrittlement plane 7. The implantation dose is greater than 8E16 at/cm² and/or the implantation current is greater than 20 mA, to achieve the conditions leading to the appearance of the defects presented in the introductory part of the present disclosure. The first layer 8 is defined in this way between the embrittlement plane 7 and the first face 6 of the donor substrate 5. Then, as shown in FIG. 3C, this first face 6 of the donor substrate is joined to an exposed face 6′ of the carrier 2, here via a dielectric interlayer 3. By way of example, the dielectric interlayer 3 may comprise or consist of silicon oxide, silicon oxynitride, or silicon nitride.

The donor substrate 5 is then fractured at the embrittlement plane 7, for example, using moderate heat treatment and/or the application of a mechanical force. The first layer 8 is then freed from the donor substrate 5 to expose a free side 9 of the first layer 8, the other face 6 of the first layer 8 being in direct contact with the dielectric interlayer 3 of the carrier 2, thereby forming the structure 10 shown in FIG. 3D.

A remaining portion 5′ of the donor substrate 5, after the removal of the first layer 8, can be reconditioned to remove a new layer, in a removal cycle similar to that just described.

It is generally necessary to provide for the finishing of the transferred first layer 8 bonded onto the carrier 2, to form a “useful” thin layer 4. These steps generally aim to improve the crystal quality of the first layer 8 and its surface condition (for example, its roughness).

As reported in the introduction to the present disclosure, this finishing comprises a step of heat treatment of the free side 9 of the first layer 8, followed by a step of thinning the first layer 8 to form the single-domain thin layer 4.

The step of heat treatment of the free side 9 of the first layer 8 may involve exposing this layer to a neutral or oxygen-containing atmosphere heated to a temperature of between 300° C. and the Curie temperature of the ferroelectric material making up the first layer 8, and for a period of between 30 minutes and 10 hours. It will be noted that this step of heat treating the free side 9 of the first layer 8 is separate from that which caused the donor substrate 5 to fracture. Indeed, with the first layer 8 not yet having been fully released during the fracture annealing, this heat treatment cannot treat a free face thereof.

The thinning step can be carried out by mechanical/chemical polishing.

In order to understand the origin of the defect in the thin layer 4 described in the introduction, a very precise analysis of the first layer 8 obtained at the end of the method shown in FIG. 3 has been carried out, i.e., prior to the finishing of this first layer 8 to prepare the single-domain thin layer 4. These analyses were carried out on a first layer 8 of lithium tantalate.

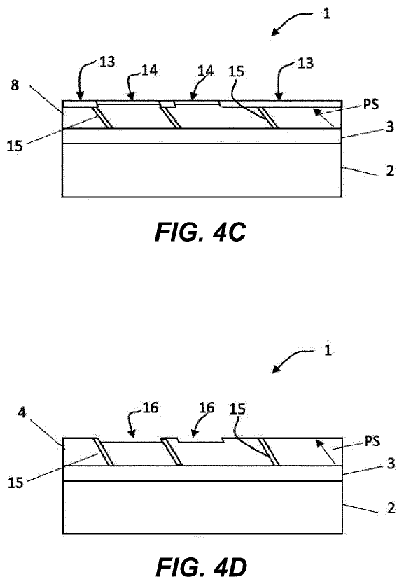

With reference to FIG. 4A, the presence of a lithium-rich surface layer 11 on the first layer 8 obtained directly after the fracturing step was observed. This surface layer 11 consists of Li₂CO₃. Its formation seems to be favored by the particular conditions in which this fracture step takes place. The presence of light species, hydrogen and/or helium, and the moderate temperature at which fracture occurs appear to make the lithium in the first layer 8 particularly mobile and the surface of this first layer 8 particularly reactive. When the remaining portion 5′ of the donor substrate is removed to expose the free side 9 of the first layer 8 to the atmosphere, this surface reacts with carbon dioxide, hydrocarbons and oxygen naturally present in the atmosphere, to form the Li₂CO₃ surface layer 11. This surface thickness, overlapping the first layer 8, is on the order of a few nanometers or more. It is stable over time, i.e., it does not change in consistency or thickness when the first layer is kept exposed to the atmosphere.

This surface layer 11 is relatively fragile, however, and it was observed that it can be removed by wet-cleaning the first layer 8.

It was also observed that the first layer 8, without its lithium-rich surface layer 11, remained particularly reactive. By keeping the free side 9 of this first layer 8 exposed to the atmosphere for an extended period of time, amorphous dendrites 12, rich in lithium and hydrogen (and other species present in the atmosphere such as chlorine or fluorine) nucleate and grow on the free side 9 of the first layer 8. This development is particularly noticeable after a period of between 50 and 75 hours. As illustrated in FIG. 4B, these dendrites 12 are distributed non-uniformly over the surface of the first layer 8; they accumulate densely in certain zones on the surface of first layer 8, in particular, on certain topologies of this surface, such as local roughness or topologies caused by the emergence of dislocations, while other zones are entirely devoid of them.

The finishing heat treatment step was applied to the first layer 8 provided with these dendrite-dense zones and other zones devoid of these dendrites.

At the end of this heat treatment, the first layer 8 (FIG. 4C) presented a multi-domain surface layer 13, as documented in the reference cited in the introduction to the present disclosure. The dendrites 12 had disappeared from the first layer 8, most likely due to dissolution during heat treatment. However, in areas of the first layer 8 that were initially dense with dendrites 12, the multi-domain surface layer had an atypical morphology 14, distinct from the morphology of this multi-domain surface layer 13 in areas initially devoid of dendrites. This atypical morphology 14 is characterized by a thinner multi-domain surface layer, as if the presence of dendrites 12 in dense zones had limited the generation of this multi-domain surface layer 13. Furthermore, the presence of triangular defects 15 in the first layer, in a density greater than 10⁴/cm² was observed.

The step of thinning was then applied by mechanical-chemical polishing to the first layer 8 obtained after heat treatment, thus providing the thin layer 4, shown in FIG. 4D. Note that the triangular defects 15 are made visible on the surface of the thin layer 4, after the first layer 8 has been treated by chemical-mechanical polishing to remove the multi-domain surface layer 13. However, these triangular defects 15 were present in the first layer 8 prior to the thinning step.

The thin layer 4 obtained showed defects of the depression type 16 in the areas of atypical morphology 14 of the multi-domain surface layer 13.

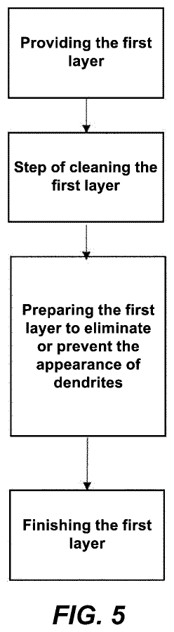

Based on these results and observations, a method for preparing a single-domain thin layer 4 of lithium-containing ferroelectric material was established. This method applies to a first single-domain layer 8 of lithium-containing ferroelectric material, bonded to a carrier 2, as shown with reference to FIG. 3 of the present disclosure and is shown in FIG. 5. Under the manufacturing conditions of this layer, the first layer therefore has a lithium-rich surface thickness 11, typically Li₂CO₃.

The preparation method is applied before finishing the first layer 8, i.e., before applying the heat treatment step to its free side 9, and before the subsequent thinning step.

This preparation method comprises a first step of wet-cleaning the free side 9 of the first layer 8. This cleaning step removes the lithium-rich surface layer, typically formed of Li₂CO₃. It may comprise or consist of brushing the free side of the first layer while dispensing deionized water onto this free side. Experiments carried out have shown that this cleaning process is perfectly suited to eliminating the Li₂CO₃ surface layer 11.

The preparation method further comprises, after the first step, a second step of preparing the first layer 8. This second step aims to eliminate dendrites or prevent/limit their appearance. These amorphous, lithium-rich and hydrogen-rich dendrites 12 are liable to nucleate on the free side of the first layer 8 when it is devoid of the lithium-rich surface layer.

This second step can be implemented in several different ways.

In a first variant, the dendrites 12 are left to develop and stabilize on the surface of the first layer 8. The second preparation step then aims to remove these dendrites 12. It is therefore applied for at least 50 hours, preferably at least 75 hours, at room temperature, after the application of the first cleaning step, so that the development of dendrites 12 is effectively stabilized. Storing substrates above room temperature could reduce this minimum waiting time by 50 hours.

In one variant, therefore, the present disclosure provides for an intermediate treatment comprising exposing the first layer 8 to a temperature higher than room temperature to promote dendrite development. In this way, waiting times can be reduced to under 50 hours. This may involve placing one or more substrates in an oven, for example, at 50° C. or in a temperature range between 27° C. and 80° C. More generally, the intermediate treatment may comprise any treatment that accelerates the formation of these dendrites, such as annealing the first layer 8.

The second preparation step can be practically implemented by a step of wet-cleaning the free side, for example, a cleaning step of the same type as that implemented to remove the Li₂CO₃ surface thickness 11. It may therefore comprise or consist of brushing the free side 9 of the first layer 8 while dispensing deionized water onto this free side.

In another variant, the free side of the first layer is treated to prevent the appearance of dendrites 12. This second preparation step is therefore applied less than 50 hours, preferably less than 10 hours, after the application of the first cleaning step. It may involve exposing the free side of the first layer to a plasma, for example, a plasma selected from the list formed by an O₂ plasma, an N₂ plasma and a fluorine-based plasma, such as an SF₆ or CₓH_{y}F_{z} plasma, or a combination of these plasmas.

A 30-second RF plasma (at 13.55 MHz) of nitrogen (N₂), with a power of 150 W and a pressure of 50 mT, in a nitrogen flow of 75 SCCM, proved particularly effective.

Similarly, a 30-second RF plasma sequence (at 13.55 MHz), at a power of 150 W and a pressure of 50 mT, in a flow of 75 SCCM oxygen and 3 SCCM SF₆ also proved effective in treating the free side 9 of the first layer 8 and preventing the appearance of dendrites 12.

The SCCM unit of measurement (“Standard Cubic Centimeters per Minute”) is a physical unit of gas mass flow, in cm³/min, at a density defined by standard temperature and pressure conditions.

The claimant observed that, unexpectedly, the application of such a plasma prevented/limited the growth and appearance of dendrites 12.

| | | | Variant 2 | Variant 2 |
|---|---|---|---|---|
| | | Variant 1 | (N₂ | (O₂/SF₆ |
| | Prior art | (cleaning) | plasma) | plasma) |
| Triangular | >1^{E}4-1^{E}6/cm² | <1^{E}2/cm² | <1^{E}2/cm² | <1^{E}2/cm² |
| defects | | | | |
| Depression | 1^{E}3-1^{E}4/cm² | Not | Not | Not |
| | | detected | detected | detected |

After applying the first cleaning step and the second step to eliminate or prevent/limit the appearance of dendrites 12, the method for manufacturing the POI structure can be continued. As already stated, this involves applying the finishing sequence to the first layer 8, to form the single-domain thin layer 4 of the final POI structure. This finishing sequence begins with heat treatment of the free side of the first layer, followed by thinning.

Advantageously, particularly in the case of the first variant of the preparation method, the time between the second step of preparing the first layer and the first cleaning step is controlled to be less than 50 hours.

Of course, the present disclosure is not limited to the embodiment described and variant embodiments can be added thereto without departing from the scope of the invention as defined by the claims.

1. A method for preparing a single-domain thin layer of lithium-containing ferroelectric material, the method comprising:
providing a first single-domain layer of lithium-containing ferroelectric material, the first single-domain layer being bonded to a carrier, the first single-domain layer having a lithium-rich surface thickness; and
finishing the first single-domain layer, this finishing comprising heat treatment of a free side of the first single-domain layer, followed by a step of thinning the first single-domain layer to form the single-domain thin layer;
wherein the preparation method comprises, prior to heat treatment:
a first step of wet cleaning of the free side of the first single-domain layer, the wet cleaning step being able to remove the lithium-rich surface layer; and
a second step of preparing the first single-domain layer to eliminate, prevent, or limit an appearance of lithium-rich and hydrogen-rich dendrites liable to nucleate on the free side of the first single-domain layer when the first single-domain layer is devoid of the lithium-rich surface layer.

2. The method of claim 1, wherein providing the first single-domain layer comprises:
implanting light species in a first face of a lithium-containing ferroelectric donor substrate to form an embrittlement plane and define the first single-domain layer between the embrittlement plane and the first face of the donor substrate;
assembling the first face of the donor substrate to the carrier by way of a dielectric interlayer; and
fracturing the donor substrate at the embrittlement plane to transfer the first single-domain layer onto the carrier and expose a free side of the first single-domain layer to an atmosphere, this exposure leading to formation of the lithium-rich surface thickness.

3. The method of claim 1, wherein the first wet cleaning step comprises brushing and dispensing deionized water onto the free side of the first single-domain layer.

4. The method of claim 1, wherein the second preparation step is a wet cleaning step of the free side of the first single-domain layer.

5. The method of claim 4, wherein the wet cleaning step of the second preparation step comprises brushing and dispensing deionized water onto the free side of the first single-domain layer.

6. The method of claim 1, wherein the second preparation step is designed to remove dendrites and is applied at least 50 hours after the application of the first wet cleaning step.

7. The method of claim 1, further comprising an intermediate step, between the first preparation step and the second preparation step, the intermediate step exposing the first single-domain layer to a temperature above ambient temperature.

8. The method of claim 1, wherein the second preparation step is designed to prevent or limit the appearance of dendrites and is applied less than 50 hours after the application of the first wet cleaning step.

9. The method of claim 8, wherein the second preparation step comprises exposing the free side of the first single-domain layer to a plasma.

10. The method of claim 9, wherein the plasma is selected from the group consisting of: an O₂ plasma, an N₂ plasma and a fluorine-based plasma, or a combination of these plasmas.

11. The method of claim 1, wherein the carrier comprises a single-piece electrically conductive or semiconductive substrate.

12. The method of claim 1, wherein the carrier comprises a base substrate and a trapping layer, the trapping layer located between the dielectric interlayer and the base substrate.

13. The method of claim 1, wherein the first single-domain layer and the single-domain thin layer consist essentially of a single-crystal piezoelectric material.

14. The method of claim 13, wherein the first single-domain layer and the single-domain thin layer consist essentially of lithium niobate.

15. The method of claim 1, wherein the dielectric interlayer comprises at least one layer of silicon oxide, silicon oxynitride, or silicon nitride.

16. The method of claim 6, wherein the second preparation step is applied at least 50 hours after the application of the first wet cleaning step.

17. The method of claim 8, wherein the second preparation step applied less than 10 hours after the application of the first wet cleaning step.

18. The method of claim 10, wherein the plasma comprises an SF₆ plasma, a CₓH_{y}F_{z} plasma, or a combination of these plasmas.

19. The method of claim 13, wherein the first single-domain layer and the single-domain thin layer consist essentially of lithium tantalate.

20. A method for preparing a single-domain thin layer of lithium-containing ferroelectric material, the method comprising:
providing a single-domain layer of lithium-containing ferroelectric material, the single-domain layer being bonded to a carrier, the single-domain layer having a lithium-rich surface thickness;
wet cleaning a surface of the single-domain layer and removing the lithium-rich surface layer;
after the wet cleaning, treating the single-domain layer to eliminate, prevent, or limit an appearance of lithium-rich and hydrogen-rich dendrites liable to nucleate on the surface of the single-domain layer when the single-domain layer is devoid of the lithium-rich surface layer; and
after the treating the single-domain layer to eliminate, prevent, or limit an appearance of lithium-rich and hydrogen-rich dendrites liable to nucleate on the surface of the single-domain layer, heat treating the single-domain layer.
